(19) United States
(12) Patent Application Publication
(10) Pub. No.: US 2025/0350101 A1
(43) Pub. Date: Nov. 13, 2025

(54) SYSTEM AND METHOD FOR DETERMINING OPERATING PARAMETERS FOR A TRANSMISISION LINE INSTALLATION SYSTEM

(71) Applicant: Condux International, Inc., Mankato, MN (US)

(72) Inventors: Bradley P. Radichel, Key Largo, FL (US); Heinz U. Wortmann, Lino Lakes, MN (US); David J. Hassing, Mankato, MN (US)

(73) Assignee: Condux International, Inc., Mankato, MN (US)

(21) Appl. No.: 19/205,699

(22) Filed: May 12, 2025

Related U.S. Application Data
(60) Provisional application No. 63/645,708, filed on May 10, 2024.

(51) Int. Cl. H02G 1/06; G01R 31/08

(52) U.S. Cl. CPC H02G 1/06; G01R 31/085

(57) ABSTRACT

A system and method for determining operating parameters for a transmission line installation system to use when installing a transmission line into a conduit. A transmission line failure testing system is used to perform testing of transmission lines and to determine failure conditions of the transmission lines. Recommended operating parameters are generated and stored in a data store. The recommended operating parameters can then be retrieved and used to setup the transmission line installation system to mitigate damage to the transmission line during transmission line installation.

### CROSS-REFERENCE TO RELATED APPLICATION(S)

This application claims the benefit of and priority to U.S. Application No. 63/645,708, filed on May 10, 2024, titled SYSTEM AND METHOD FOR DETERMINING OPERATING PARAMETERS FOR A TRANSMISSION LINE INSTALLATION SYSTEM, the disclosure of which is hereby incorporated by reference in its entirety.

### BACKGROUND

Transmission lines are used for transmitting power or data signals. One type of transmission line is a fiber optic cable that can be used to transmit digital data using light signals. The use of fiber optic cable for data transmission is popular, at least in part due to the high data transmission rate and very fast transmission speed.

Transmission lines can be used to carry power or data signals short distances, such as within a building, or long distances, such as between neighboring cities. For longer distance communication, transmission lines are often installed in underground conduits, such as ducts, where continuous transmission lines can span 0.5, 1, 2, 5 kilometers, or more.

Installation equipment such as transmission line blowers and transmission line pullers have been developed that can be used to insert transmission lines into ducts over long distances. However, even with the proper installation equipment, there are many variables that impact whether such an installation will be successful.

In order to successfully install a transmission line over long distances, the transmission line installation equipment must operate at sufficient levels to ensure that the transmission line does not stop short of its destination. A failed installation may require withdrawing the transmission line and retrying the installation. Alternatively, the leading end of the transmission line may need to be located and accessed (which can be particularly challenging with underground ducts) in order to resume the transmission line installation using transmission line installation equipment from that location.

On the other hand, if the transmission line installation is too aggressive, the transmission line may be damaged. A damaged transmission line can delay the installation project, and may require that a new transmission line be obtained at significant additional cost.

Due to the many variables that can affect an installation, it is difficult to predict whether a given installation will successfully reach its destination, or whether the transmission line will be damaged during the installation.

### SUMMARY

In general terms, this disclosure is directed to transmission line installation. In a non-limiting example, the disclosure relates to a system and method for determining operating parameters for a transmission line installation system.

One aspect is a method for mitigating damage to a transmission line during installation, the method comprising: conducting failure testing to determine a failure condition of a transmission line; determining recommended operating parameters for installation of the transmission line using a transmission line installation system based at least in part on the failure testing; storing the recommended operating parameters in a data store; retrieving the recommended operating parameters from the data store; setting up the transmission line installation system based at least in part on the recommended operating parameters; and installing a transmission line using the transmission line installation system.

Another aspect is a method for generating recommended installation parameters associated with a transmission line, the method comprising: testing the transmission line at a transmission line testing system to generate test run data; accessing the test run data at an operating parameters provider; identifying test runs having selected characteristics; identifying maximum operating parameters resulting in a passing test within the test runs having selected characteristics; and assigning recommended operating parameters based at least in part on the maximum operating parameters.

A further aspect is a system for determining recommended operating parameters for a transmission line installation system, the system comprising; a transmission line failure testing system configured to perform tests on one or more transmission lines to generate test run data; an operating parameters provider configured to receive the test run data from the transmission line failure testing system, generate recommended operating parameters from the test run data, and store the recommended operating parameters at an operating parameters database; and a transmission line installation system configured to receive the recommended operating parameters from the operating parameters provider, and install a transmission line according to the recommended operating parameters.

### BRIEF DESCRIPTION OF THE DRAWINGS

FIG. 1 is schematic block diagram illustrating an example system for determining operating parameters for a transmission line installation system.

FIG. 2 is a flow chart illustrating an example method for determining operating parameters for a transmission line installation system.

FIG. 3 is a schematic block diagram of a transmission line failure testing system.

FIG. 4 is a flow chart illustrating an example method of transmission line failure testing.

FIG. 5 is a schematic diagram illustrating test runs at the transmission line failure testing system.

FIG. 6 is a schematic block diagram illustrating test run data being transmitted from the transmission line failure testing system to the operating parameters provider.

FIG. 7 is a flow chart illustrating an example method of generating recommended operating parameters.

FIG. 8 is a schematic block diagram illustrating operating parameters generated from test run data at the operating parameters provider.

FIG. 9 is a flow chart illustrating an example method of setting up a transmission line installation system.

FIG. 10 is a schematic block diagram illustrating recommended operating parameters generated at the operating parameters provider in response to installation specifications received from the transmission line installation system.

FIG. 11 is a perspective view illustrating portions of the transmission line installation system shown in FIG. 1.

FIG. 12 is a schematic block diagram illustrating installation specifications being transmitted from the transmission line installation system to the operating parameters provider.

FIG. 13 is a schematic block diagram illustrating recommended operating parameters being received at the transmission line installation system.

FIG. 14 illustrates an example user interface for monitoring run data during transmission line installation.

FIG. 15 is a perspective view of the example line conveying apparatus shown in FIG. 11.

FIG. 16 is a schematic block diagram of the example transmission line installation system shown in FIG. 11.

FIG. 17 is a flow chart illustrating an example method of transmission line installation.

FIG. 18 is a flow chart illustrating an example method of transmission line installation.

### DETAILED DESCRIPTION

Various embodiments will be described in detail with reference to the drawings, wherein the reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

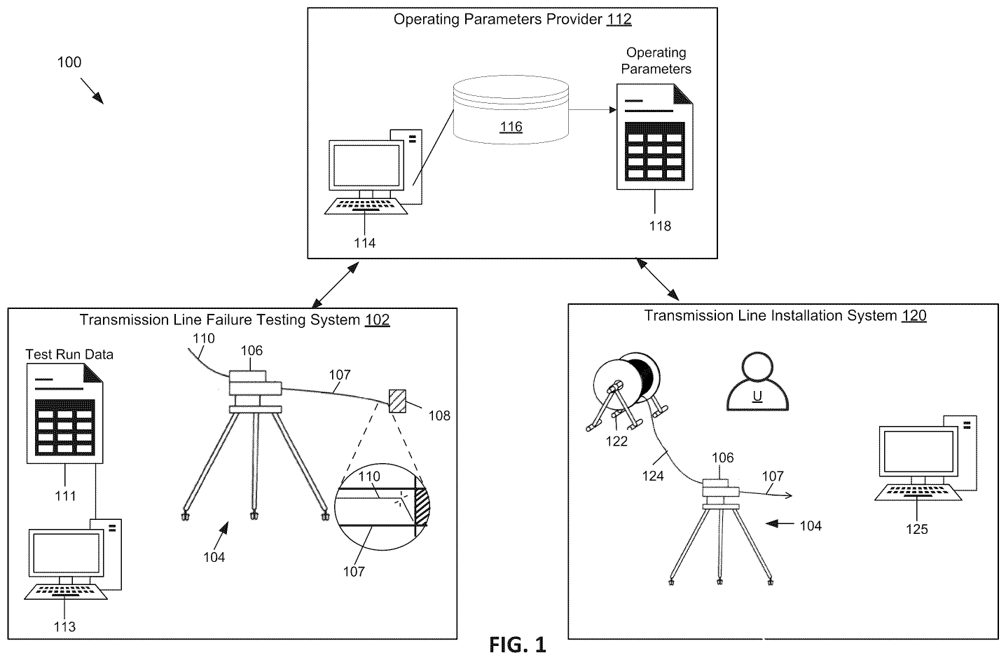

FIG. 1 is a schematic block diagram illustrating a system 100 for determining operating parameters for a transmission line installation system 120. In the example illustrated in FIG. 1, the system 100 includes a transmission line failure testing system 102, an operating parameters provider 112, and a transmission line installation system 120. The transmission line failure testing system 102 includes, for example, a transmission line conveying apparatus 104 (including an advancement device 106), a conduit 107, an obstruction 108, a transmission line 110, test run data 111, and a computing device 113. The example operating parameters provider 112 includes a computing device 114, an operating parameters database 116, and operating parameters 118. The example transmission line installation system 120 includes a transmission line source 122, a transmission line 124, a computing device 125, and a transmission line conveying apparatus 104 (including an advancement device 106). The transmission line installation system 120 operator is also illustrated as operator U.

In the illustrated example, the system 100 operates to determine recommended operating parameters 118 for a transmission line installation system 120. For example, the operating parameters 118 are used for the installation of a transmission line 124 based on testing conducted at the transmission line failure testing system 102. In some embodiments, a long run (e.g., 0.5, 1, 2, 5 kilometers, or more) installation of the transmission line 124 can be achieved by using the operating parameters 118, which simultaneously reduces the chance of damaging the transmission line 124 by ensuring that the operating parameters 118 remain below one or more threshold values. Further, the setup time of the transmission line installation system 120 is reduced by not requiring that crash testing (or similar operational testing) take place in the field, due to the fact that such testing has previously been performed by the transmission line failure testing system 102.

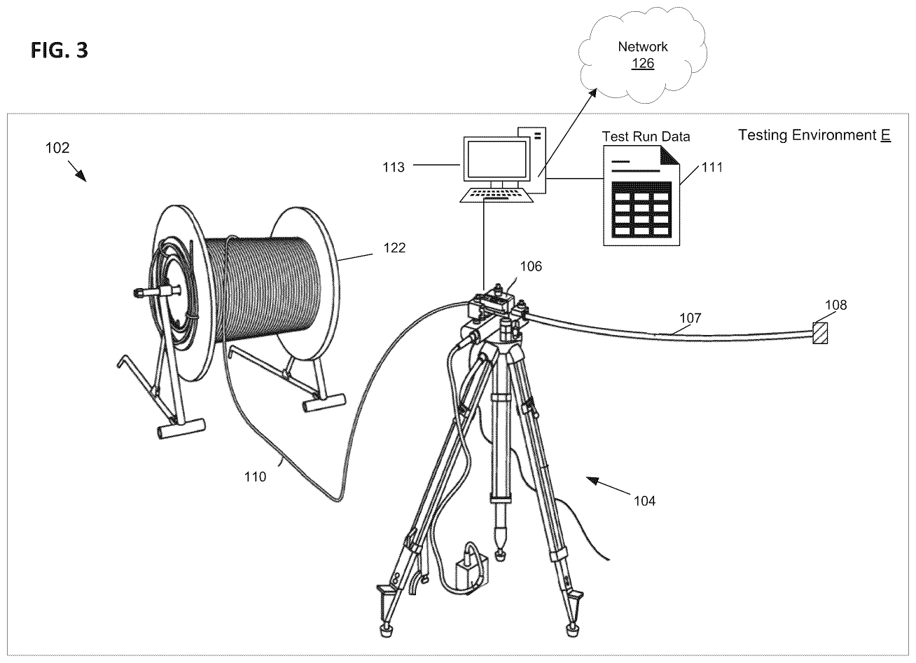

The example transmission line failure testing system 102 operates to perform tests on one or more transmission lines 110, such as to determine failure criteria of the transmission line 110 during transmission line installation. In this example, the transmission line failure testing system 102 includes a transmission line conveying apparatus 104, which operates to propel the transmission line 110, such as into and through the conduit 107. In this example the transmission line conveying apparatus 104 includes an advancement device 106, such as a line blower. In another possible embodiment, the apparatus 104 can include a tractor drive without a line blower. An example of the advancement device 106 is illustrated and described in further detail with reference to FIG. 3, with additional examples being described throughout this description.

In some embodiments, the transmission line failure testing system 102 operates to simulate an obstruction 108 being present along the conduit 107 during an installation of the transmission line 110 into the conduit 107. As an example, an obstruction 108 is arranged in or at the end of a segment of conduit 107 to simulate a blockage along the installation path. In some embodiments the transmission line failure testing system 102 replicates various environmental factors as well, such as temperature and humidity. Examples of the transmission line failure testing system 102 are illustrated and described in further detail with reference to FIGS. 3-6.

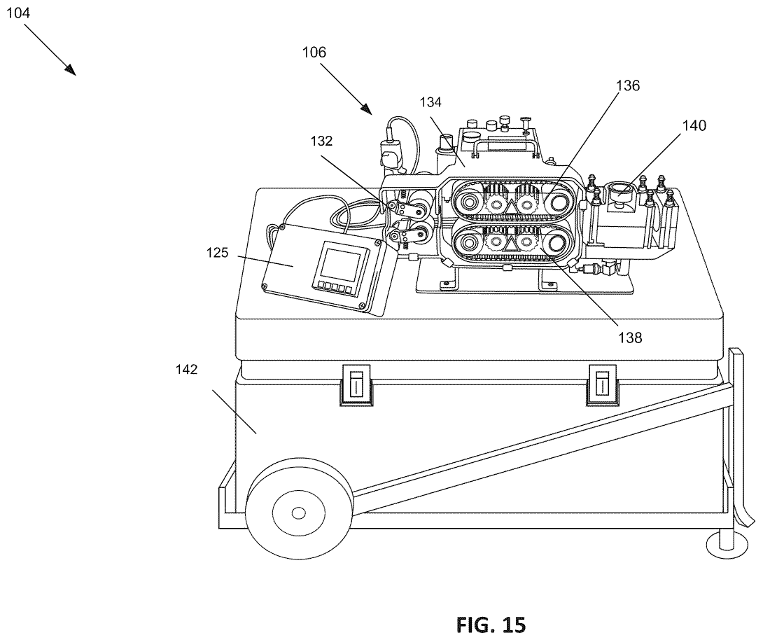

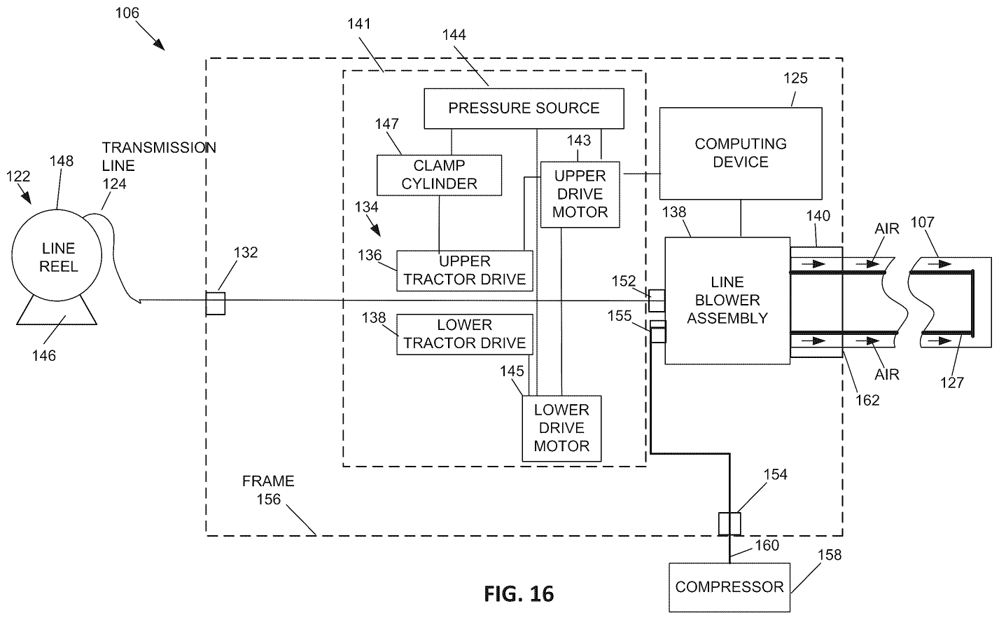

The advancement device 106 is a part of the transmission line conveying apparatus 104 that operates to advance a transmission line 110 during transmission line installation. An example of an advancement device 106 is a line blower. Examples of line blowers are illustrated and described in further detail herein with reference to FIGS. 15-16. In some embodiments the line blower includes a tractor drive. In yet other embodiments, the advancement device 106 includes a tractor drive and does not include a blower. Other advancement devices 106 can be used in other embodiments. In some embodiments the advancement device 106 has one or more operating parameters that can be adjusted. For example, a tractor drive portion of the advancement device 106 can apply a variable push force, a variable clamp force, or both, to the transmission line 110. The push force can be adjusted to apply a stronger or a weaker push force. The clamp force can be adjusted to apply a stronger or a weaker clamp force. The variable push force and the variable clamp force are examples of operating parameters of the transmission line conveying apparatus 104, and of the advancement device 106. A variable pulling force can also be applied by a line blower assembly (not shown).

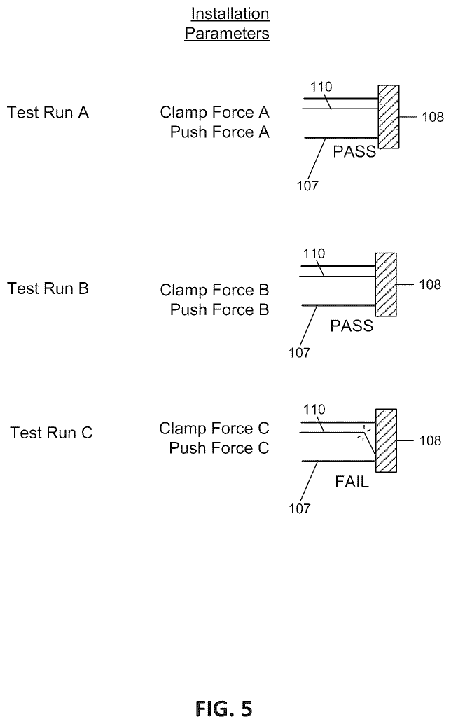

In the example shown, the transmission line conveying apparatus 104 performs a test run by conveying a length of the transmission line 110 at selected operating parameters (such as a selected push force, a selected clamp force, or a selected pulling force). The transmission line 110 can be inspected after a test run to determine whether the transmission line 110 was damaged during the test run, such as illustrated and described in further detail with reference to FIG. 5. An evaluation is made to determine the results of the test run. For example, if the transmission line 110 is intact (e.g., not damaged), a determination is made that the test passed. If the transmission line 110 is damaged, then a determination is made that the test failed.

In some embodiments, test run data 111 is recorded for each test run. The test run data 111 can include the characteristics of the transmission line, the operating parameters that were used for the test run, and whether the test passed or failed. For example, test run data 111 can be recorded by the computing device 113 of the failure testing system 102. In some embodiments the computing device 113 automatically monitors and records test run data 111, and in other embodiments at least some of the test run data 111 (such as test results, for example) is manually entered by the operator U. In some embodiments, the computing device 113 is part of the transmission line conveying apparatus 104 (or advancement device 106), and in other embodiments the computing device 113 is separate from the transmission line conveying apparatus 104 (or advancement device 106).

In some embodiments, the transmission line failure testing system 102 is in communication with the operating parameters provider 112. The transmission line failure testing system 102 can send and receive the test run data 111 to and from the operating parameters provider 112. For example, the computing device 113 can transmit the test run data 111 to the operating parameters provider 112.

The operating parameters provider 112 is a system that receives and converts test run data 111 into the operating parameters 118 that can be stored and subsequently transmitted to one or more transmission line installation systems 120. For example, the operating parameters provider 112 can send and receive information previously received from the transmission line failure testing system 102. In this example, the operating parameters provider 112 receives the test run data 111 at a computing device 114. In some embodiments, the test run data 111 can be stored at the operating parameter database 116. In this example, the computing device 114 operates to generate the operating parameters 118 from the test run data 111. The operating parameters 118 can be stored at the operating parameter database 116.

In some embodiments, the operating parameters provider 112 is in further communication with a transmission line installation system 120, such as through one or more data communication networks. The operating parameters provider 112 can send and receive information from the transmission line installation system 120. For example, the operating parameters 118 can be sent to the transmission line installation system 120.

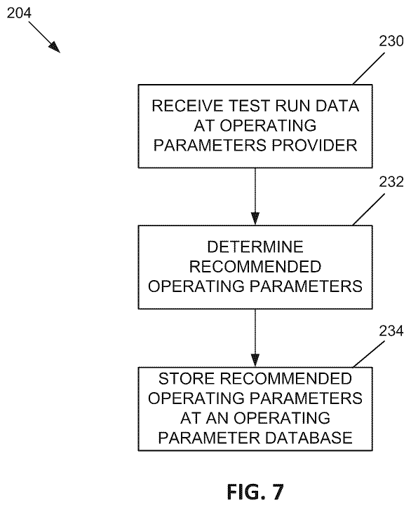

Examples of the operating parameters provider 112 are illustrated and described in more detail with reference to FIGS. 7-10.

The transmission line installation system 120 operates to install a transmission line into a conduit. In this example, the transmission line installation system 120 includes a transmission line source 122, a transmission line 124, a computing device 125, a line conveying apparatus 104, and an advancement device 106. In this example, an operator U is also shown.

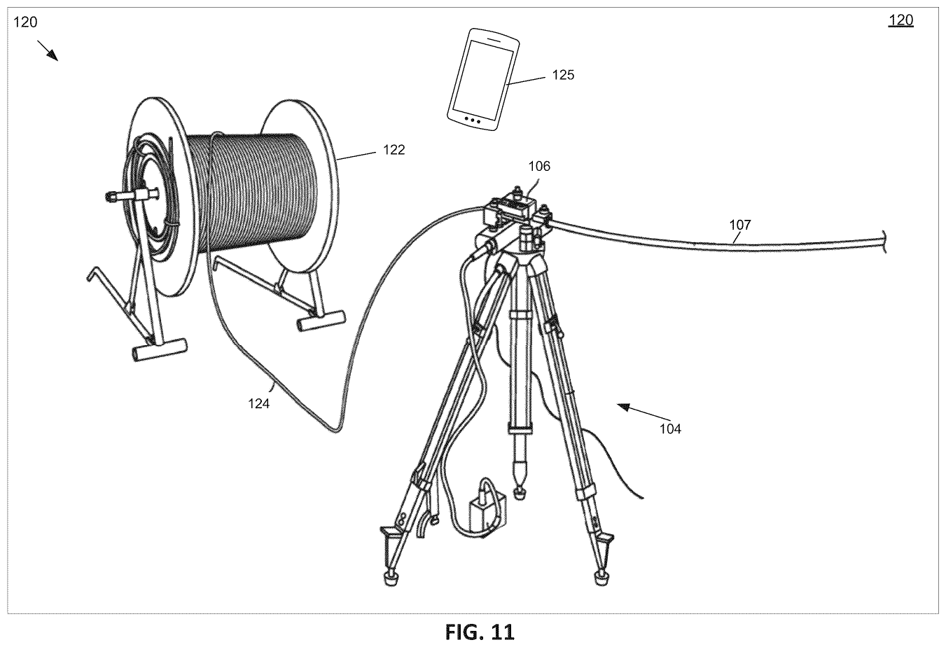

In some embodiments, the transmission line installation system 120 includes a transmission line source 122 on which a transmission line 124 is originally stored. The transmission line conveying apparatus 104 is a machine that operates to install the transmission line 124 into a conduit 107. In the example shown, the transmission line conveying apparatus 104 includes an advancement device 106. The advancement device 106 may be the same or different from the device used in the transmission line failure testing system 102. In some embodiments the advancement device 106 of the transmission line installation system 120 is selected to be a same type as at least one of the advancement devices 106 used in the transmission line failure testing system 102. Examples of the transmission line installation system 120 are described in more detail herein, such as with reference to FIGS. 11-18.

In some embodiments, the transmission line installation system 120 can send and receive information to and from the operating parameters provider 112. In this example, the transmission line conveying apparatus 104 is set up and may be operated by or monitored by an operator U. In some embodiments, the computing device 125 of the transmission installation system 120 receives input from the operator U to determine installation specifications of the transmission line installation system 120. In some embodiments, the computing device 125 can be separate from the transmission line installation system 120. The installation specifications are sent by the computing device 125 to the operating parameters provider 112, which uses the installation specifications to determine appropriate operating parameters 118 for the transmission line installation system 120. The operating parameters 118 are sent by the computing device 114 of the operating parameters provider 112 to the transmission line installation system 120. Once the operating parameters 118 are received by the transmission line installation system 120, the transmission line installation system 120 can operate to install the transmission line 124 according to the operating parameters 118.

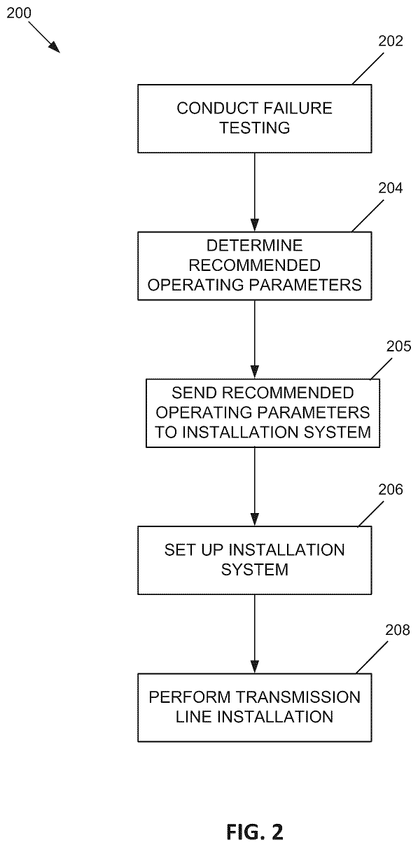

FIG. 2 is a flow chart illustrating an example method 200 of installing a transmission line using the system 100 and the transmission line installation system 120 (illustrated in FIG. 1). In this example, the method 200 includes operations 202, 204, 206, and 208. Other embodiments can include more, fewer, or different operations than the example illustrated in FIG. 2.

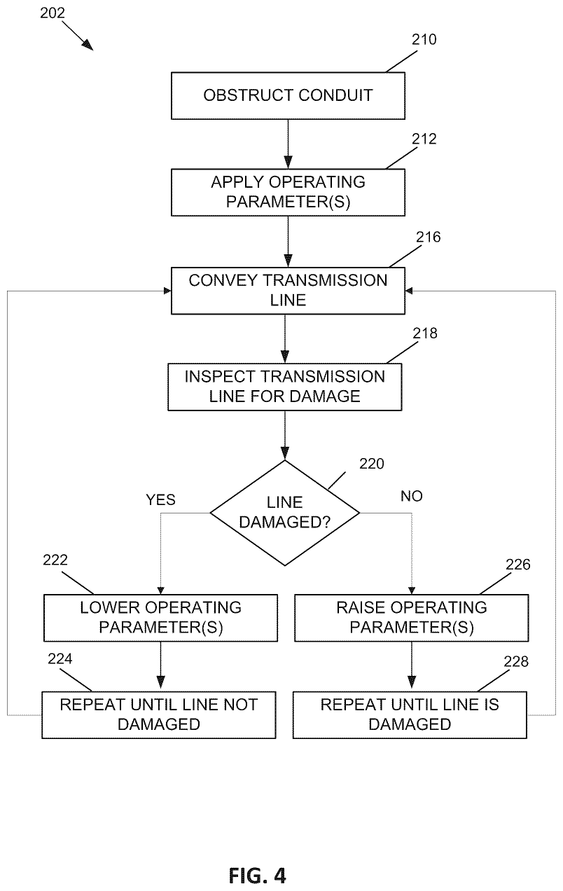

The operation 202 is performed to conduct failure testing. For example, a transmission line 110 can be tested to determine failure conditions of the transmission line. An example of the operation 202 is illustrated and described in further detail with reference to FIG. 4.

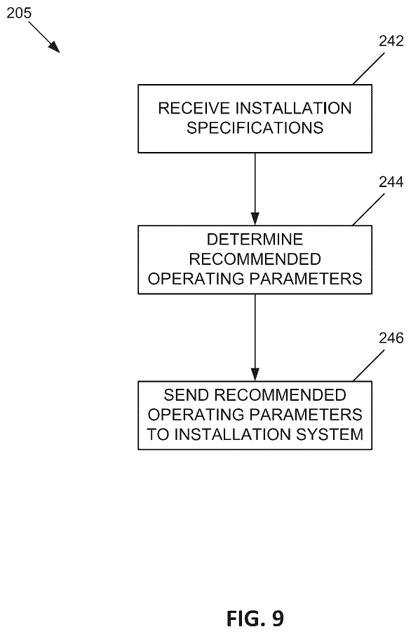

The operation 204 is performed to determine recommended operating parameters 118. In some embodiments, the operating parameters 118 are determined based on installation specifications of a transmission line installation system. For example, the installation specifications can include at least one of: (i) a type of transmission line conveying apparatus, (ii) a type of transmission line, (iii) a type of conduit, (iv) environmental conditions, or (v) combinations of (i), (ii), (iii), or (iv). An example of operation 204 is illustrated and described in further detail with reference to FIG. 7 and FIG. 9.

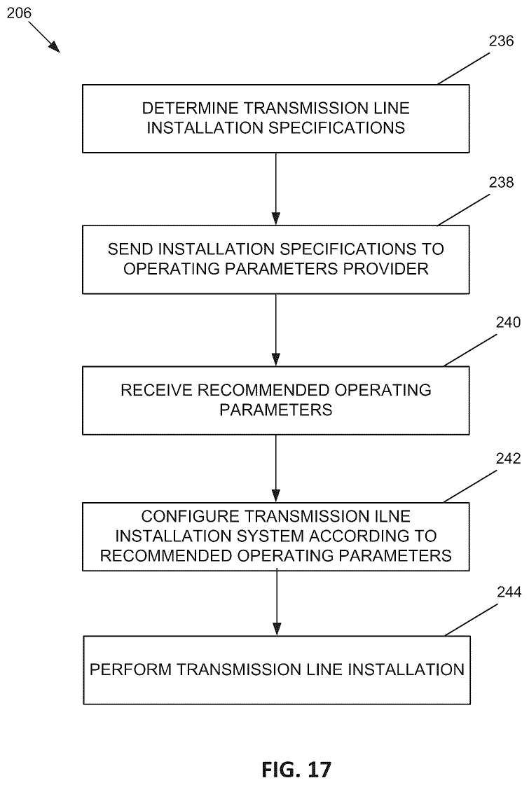

The operation 206 is performed to set up a transmission line installation system 120. For example, the transmission line installation system 120 can be set up using the recommended operating parameters 118. Examples of operation 206 are illustrated and described in further detail with reference to FIG. 17.

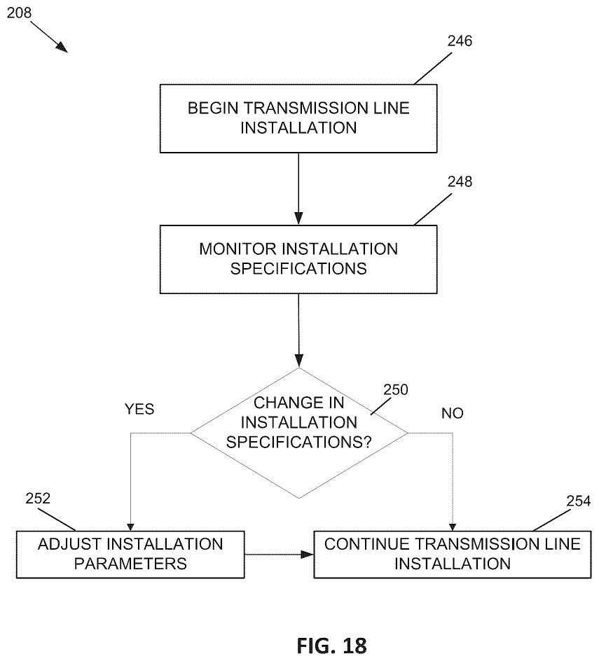

Once the transmission line installation system 120 is set up, operation 208 is performed to install a transmission line 124. An example of operation 208 is illustrated and described in further detail with reference to FIG. 18.

FIG. 3 is a schematic block diagram of a transmission line failure testing system 102. In particular, a transmission line source 122, transmission line 110, transmission line conveying apparatus 104, conduit 107, an obstruction 108, a computing device 113, and network 126 are shown. In this example, the blower system 104 includes an advancement device 106.

In this example, the transmission line failure testing system 102 is located in a testing environment E. In some embodiments the testing environment E is separate from the field where transmission lines are installed by the transmission line installation system 120 (FIG. 1). An example of the testing environment E is a laboratory environment, such as a pilot installation space. The example transmission line failure testing system 102 operates to perform tests on one or more transmission lines 110, such as to determine failure criteria of the transmission line 110 during transmission line installation.

The transmission line source 122 includes a transmission line 110 to be conveyed by the conveying apparatus 104. In some embodiments the transmission line source includes a reel and reel stand, as discussed in further detail herein. In other embodiments, the transmission line 110 is a length of the transmission line 110. The length of the transmission line 110 used by the transmission line failure testing system 102 is typically much less than the length used by the transmission line installation system 120 during an actual transmission line installation.

The transmission line 110 is fed into the transmission line conveying apparatus 104. The transmission line 110 can be one of a variety of different types of transmission lines, such as a wire, a cable, or other elongate structure capable of transmitting energy. Examples of transmission line 110 include a fiber optic cable, a power line, an electrical cable, a telephone line (copper line), a coaxial cable, or the like.

The transmission line conveying apparatus 104 is a machine that operates to propel the transmission line 110, such as into and through the conduit 107 and into an obstruction 108. A variety of different transmission line conveying apparatuses 104 can be used in various embodiments.

The advancement device 106 is a part of the transmission line conveying apparatus 104 that operates to advance a transmission line 110 during transmission line installation. An example of an advancement device 106 is a line blower. In the example shown, the transmission line conveying apparatus 104 performs a test run by conveying a length of the transmission line 110 at selected operating parameters (such as a selected push force and a selected clamp force).

The conduit 107 receives the transmission line 124 after it is advanced by the advancement device 106. An example of the conduit 107 is a duct. Conduit 107 can have a variety of configurations, including different inner and outer diameters, different thicknesses, different surface textures, different surface coatings, and different material compositions.

The obstruction 108 simulates an obstruction present along the conduit 107 during an installation of the transmission line 110 into the conduit 107. As an example, the obstruction 108 is arranged in or at the end of a segment of conduit 107 to simulate a blockage along the installation path, such as a rock, tree root, sharp corner, or crimp in the conduit 107. The obstruction 108 can be a plug, a cap, a wall, or other barrier that prevents the transmission line 110 from running freely through an end of the conduit 107. For example, the obstruction 108 can be a plug of a diameter that may be inserted into a distal end of the conduit 107 with a particular diameter corresponding to the inner or outer diameter of the conduit 107. In some embodiments, the obstruction 108 is arranged inside of the conduit 107. In some embodiments, the obstruction is arranged at the end of a segment of the conduit 107.

The computing device 113 is used to record test data 111. In some embodiments, the computing device 113 is part of the transmission line conveying apparatus 104 or the advancement device 106. In other embodiments the computing device 113 is separate from transmission line conveying apparatus 104 or the advancement device 106. In the illustrated example, a network 126 is also shown for communication between the computing device 113 and other systems. In some examples, test run data 111 can be recorded by the computing device 113 of the transmission line failure testing system 102. In some embodiments, the computing device 113 is separate from the transmission line failure testing system 102.

The network 126 is shown for communication between the transmission line failure testing system 102 and other systems. The network 126 is one or more data communication networks that individually or collectively provide a data communication channel between the transmission line failure testing system 102 and other systems. An example of the network 126 is the Internet. In various embodiments, the network 126 includes one or more data communication channels, which may include multiple different types. For example, the network 126 can include wired and wireless data communication channels, such as cellular, WI-FI®, BLUETOOTH®, satellite, or fiber optic communication channels, or combinations of these.

In some embodiments the transmission line failure testing system 102 replicates various environmental factors that can affect the properties of the transmission line 110 or conduit 107. Environmental factors that can be replicated include at least one of: temperature, humidity, sunlight, shade, precipitation, or combinations thereof. One or more of the environmental factors may be altered for a test run. For example, a first series of test runs may be completed at a first humidity before performing a second series of test runs at a second humidity. Test runs may be performed any number of times with various environmental factors or combinations of environmental factors.

In some embodiments, the operating parameters can be adjusted until one or more failure criteria of the transmission line 110 are determined for a particular set of environmental factors. The operating parameters can include a clamp force. The operating parameters can include a push force. In some embodiments, the failure criteria are the operating parameters that resulted in a failed test run. For example, to determine whether a test run failed, the transmission line 110 can be inspected after the test run to determine whether the transmission line 110 was damaged during the test run. An evaluation is made to determine the results of the test run. For example, if the transmission line 110 is intact (e.g., not damaged), a determination is made that the test passed. If the transmission line 110 is damaged, then a determination is made that the test failed. Damage to the transmission line can be determined visually, such as a bend or loop in the transmission line, or by performing a test on the transmission line. For example, a light transmission test can be performed to determine the amount of light that passes through the transmission line. In some embodiments, an amount of damage to a transmission line can be indicated by a certain reduction in performance determined through light transmission testing. Environmental factors, operating parameters, or transmission line conveying apparatuses 104 may be adjusted as variables until there is a failed test run. In some examples, at least one operating parameter or at least one environmental condition are adjusted until there is a failed test run. In some examples, multiple operating parameters, multiple environmental conditions, or a combination of operating parameters and environmental conditions can be adjusted until there is a failed test run. It is also possible that a range of operating parameters may not result in failure of the transmission line, and provided that the range of operating parameters is acceptable, it may not be necessary to reach the point of failure for that series of test runs. In other words, it can be determined that any of the operating parameters within the range are acceptable operating parameters that are unlikely to result in damage to the transmission line.

In some embodiments a variety of different transmission line conveying apparatuses 104 may be used for various test runs.

In some embodiments, test run data 111 is recorded for each test run. The test run data 111 can include the characteristics of the transmission line 110, the characteristics of the advancement device 106, the environmental factors, the operating parameters that were used for the test run, and whether the test passed or failed.

In some examples, the characteristics of the transmission line 110 can include a transmission line identifier. One example of a transmission line identifier is the manufacturer identification number, manufacturer name, or model name of the transmission line. In some examples, the characteristics of the transmission line 110 can include a variety of the known characteristics of the transmission line 110. For example, characteristics of the transmission line 110 can also include a material composition of the transmission line, such as an outer jacket material, strength member material, core material, coating materials or cladding materials. Characteristics of the transmission line 110 can also include dimension information, such as an outer diameter or an inner diameter.

In some examples, the characteristics of the advancement device 106 can include an advancement device identifier. One example of an advancement identifier is the manufacturer identification number, manufacturer name, or model name of the advancement device 106. In some examples, the characteristics of the advancement device can include a variety of the known characteristics of the advancement device 106. For example, characteristics of the advancement device can also one or more of: a maximum push force, a minimum push force, a maximum clamp force, a minimum clamp force, the transmission line size range that can be installed by the advancement device 106, a conduit size range that can be accommodated by the advancement device, a blower size, power parameters, drive parameters, control parameters, air flow requirements, air pressure requirements, average speed, lubrication requirements, lubrication compositions, sealing parameters, or combinations thereof.

In some embodiments, the transmission line failure testing system 102 is in communication with the operating parameters provider 112 (shown in FIG. 1). The transmission line failure testing system 102 can send and receive the test run data 111 to and from the operating parameters provider 112. For example, the computing device 113 can transmit the test run data 111 to the operating parameters provider 112. In this example, test run data 111 can be transmitted across the network 126. Test run data 111 can be stored in a database (not shown in FIG. 3) of the transmission line failure testing system 102. In some embodiments, test run data 111 can be stored outside of the transmission line failure testing system 102. For example, test run data can be stored at the operating parameters provider 112. The operating parameters provider 112 is described in further detail below.

FIG. 4 is a flow chart illustrating an example method of conducting transmission line failure testing. In this example, the method includes operations 210, 212, 214, 216, 218, 220, 222, 224, 226, and 228.

The operation 210 is performed to obstruct a conduit 107. Similar to the transmission line failure testing system 102 discussed in FIG. 3, the operation 210 is performed to simulate an obstruction, such as a rock, crimp, or other obstruction in the conduit 107, that may be encountered while installing a transmission line 110.

The operation 212 is performed to apply one or more operating parameters at the transmission line conveying apparatus 104 (including the advancement device 106). The operating parameters can include a push force, a clamp force, an air pressure, or other parameters. The push force and clamp force can be measured, for example, in Newtons, pounds, or pounds per square inch (PSI). The air pressure can be measured, for example, in millimeters of mercury, PSI, Pascals, standard atmospheres, millibars, or dynes per square centimeter.

The operation 216 is performed to convey a transmission line 110 through the transmission line conveying apparatus 104 and into the obstruction 108. In some examples, the operating parameters may be too weak to convey the transmission line. In those circumstances, the operating parameters will need to be raised. In some embodiments the result of the test will be marked as failed, because the operating parameters were insufficient to advance the transmission line.

The operation 218 is performed to inspect the transmission line for damage. For example, as discussed in relation to FIG. 3, damage can be inspected visually or by testing the transmission line. The operation 220 is performed to determine whether the transmission line has been damaged based on the inspection of operation 218. In some instances, the transmission line may have become damaged even though the operating parameters were too weak to convey the transmission line due to tractor drive slips damaging the transmission line.

If the transmission line 110 is damaged, the operation 222 is performed to lower one or more operating parameters. For example, the clamp force can be adjusted to apply a weaker clamp force. In another example, the push force can be adjusted to apply a weaker push force. In some embodiments more than one operating parameters is lowered. In some embodiments, only one operating parameter is lowered. In some embodiments, only one operating parameter is lowered. After one or more operating parameters are lowered at operation 222, operation 224 is performed to repeat testing beginning at operation 216 until the transmission line 110 is not damaged. In other examples, operation 226 may be performed to raise one or more operating parameters. For example, as discussed above, if the operating parameters were too weak to convey the transmission line, but nonetheless caused damage to the transmission line, the operating parameters can be raised at operation 226. In some embodiments, a new transmission line 110 of the same characteristics is provided for each test, whereas in other embodiments the transmission line 110 is reused until it is damaged.

If the transmission line 110 is not damaged, the operation 226 is performed to raise one or more operating parameters. For example, the clamp force can be adjusted to apply a stronger clamp force. In another example, the push force can be adjusted to apply a stronger push force. In some embodiments more than one of the operating parameters are raised. In some embodiments, only one operating parameter is raised. After one or more operating parameters are raised at operation 226, operation 228 is performed to repeat testing, beginning at operation 216, until the transmission line 110 is damaged. In some embodiments, a new transmission line 110 of the same characteristics is provided for each test, and in other embodiments the transmission line 110 is reused for multiple tests until it is damaged. In some embodiments, the operating parameters initially selected may be intentionally low so that the operating parameters will be increased until the transmission line installation fails.

FIG. 5 is a schematic diagram illustrating test runs at the transmission line failure testing system. In the example, three test runs are performed: test run A, test run B, and test run C.

At test run A, operating parameters are applied to advance a transmission line 110 into an obstruction 108 at the end of a conduit 107. For example, the operating parameters can include a clamp force A and a push force A. Alternative or additional operating parameters are also possible including a pulling force. As illustrated by the straight transmission line 110, the transmission line 110 did not become damaged, indicating that test run A passed.

At test run B, operating parameters are applied to advance a transmission line 110 into an obstruction 108 at the end of a conduit 107. For example, the operating parameters can include a clamp force B and a push force B. In some embodiments, one or more of the operating parameters at test run B can be different from the operating parameters at test run A. In some embodiments, or more of the operating parameters at test run B can be the same as the operating parameters at test run A. As illustrated by the straight transmission line 110, the transmission line 110 did not become damaged, indicating that test run B passed.

At test run C, operating parameters are applied to advance a transmission line 110 into an obstruction 108 at the end of a conduit 107. For example, the operating parameters can include a clamp force C and a push force C. In some embodiments, one or more of the operating parameters at test run C can be different from the operating parameters at test run B. In some embodiments, one or more of the operating parameters at test run C can be the same as the operating parameters at test run B. As illustrated by the bend in the transmission line 110, the transmission line 110 is damaged, indicating that test run B failed.

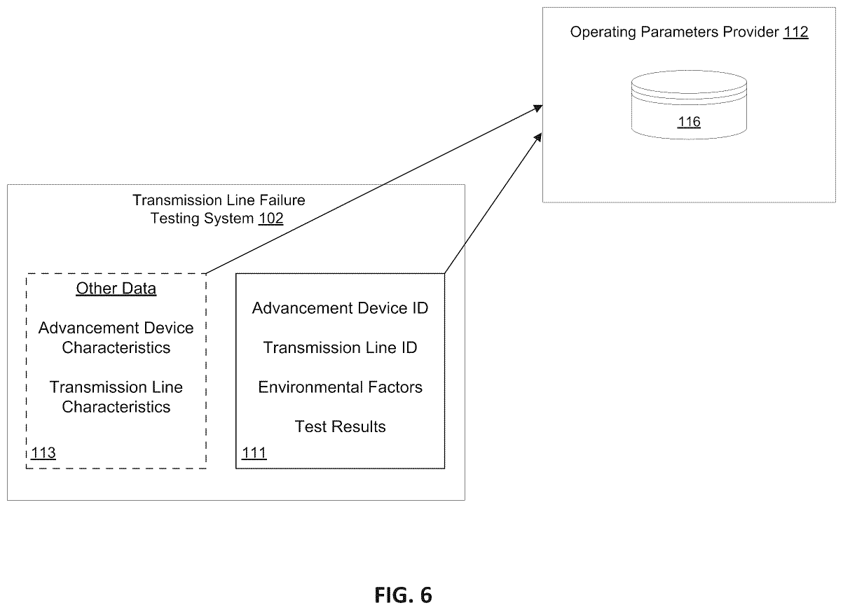

FIG. 6 is a schematic block diagram illustrating data being transmitted from the transmission line failure testing system 102 to the operating parameters provider 112. In the example illustrated in FIG. 6, the transmission line failure testing system 102 includes test run data 111 and other data 115. The example operating parameters provider 112 includes an operating parameters database 116.

As illustrated in FIG. 6, the test run data 111 can include an advancement line identifier, a transmission line identifier, environmental factors, and test results. The environmental factors can, for example, be the environmental factors present for a given failure test. As discussed, environmental factors can include temperature, humidity, sunlight, shade, and precipitation. In some embodiments, the test results can be a determination of whether a given test passed or failed.

Still in reference to FIG. 6, the transmission line failure testing system 102 can optionally include other data 115. Other data 115 can include a variety of known advancement device characteristics and/or a variety of transmission line characteristics, or other information, Examples of advancement device characteristics include a maximum push force, a minimum push force, a maximum clamp force, a minimum clamp force, the transmission line size range that can be installed by the advancement device, a conduit size range that can be accommodated by the advancement device, a blower size, power parameters, drive parameters, control parameters, air flow requirements, air pressure requirements, average speed, lubrication requirements, lubrication compositions, sealing parameters, or combinations thereof. Examples of transmission line characteristics include a material composition of the transmission line, such as an outer jacket material, strength member material, core material, coating materials, cladding materials, dimension information, such as an outer diameter or inner diameter, or combinations thereof.

As further illustrated in FIG. 6, the transmission line failure testing system 102 is in communication with the operating parameters provider 112. The transmission line failure testing system 102 can transmit the test run data 111 to the operating parameter database 116 of the operating parameters provider 112 for storage. In some embodiments the transmission line failure testing system 102 can also transmit other data 115 to the operating parameters database 116. In some embodiments, the test run data 111 can be accessed at the operating parameter database 116 for further processing by the operating parameters provider 112 or other systems.

The operating parameters database 116 is an example of a data store. A data store is a non-transitory computer-readable data storage system that stores digital data.

FIG. 7 is a flow chart illustrating an example method of generating a database of recommended operating parameters 118. In this example, the method 204 includes operations 230, 232, and 234.

The operation 230 is performed to receive test run data 111 at an operating parameters provider 112. In some embodiments, the operating parameters provider 112 can receive the test run data 111 at the computing device 114. An example of operation 230 is illustrated and described in more detail herein with reference to FIG. 6.

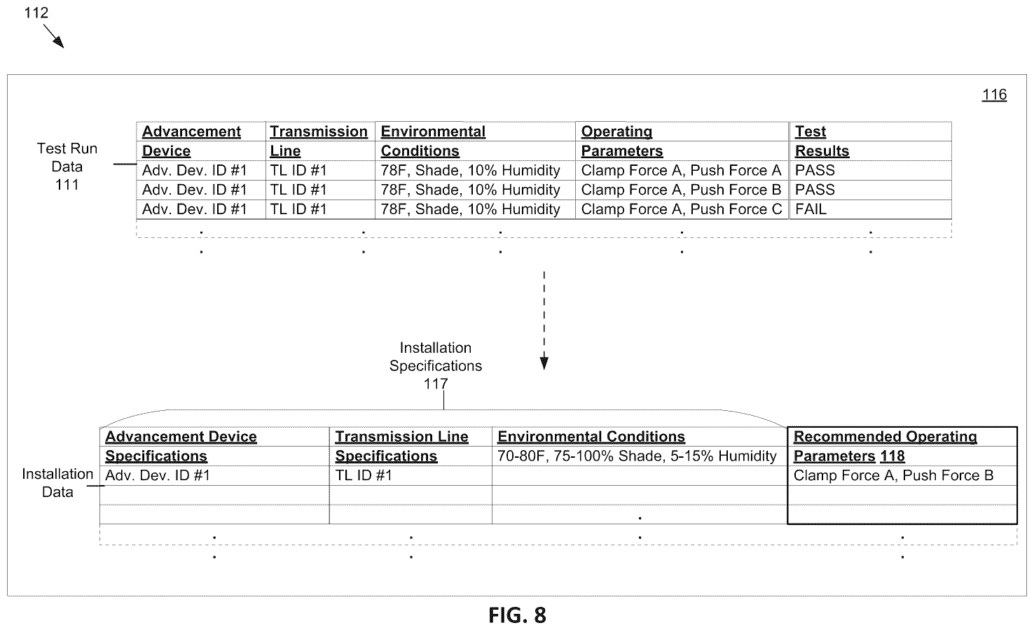

The operation 232 is performed to determine recommended operating parameters 118. In some embodiments, the computing device 114 operates to generate the recommended operating parameters 118 from the test run data 111. An example of operation 232 is illustrated and described in more detail herein with reference to FIG. 8.

The operation 234 is performed to store the recommended operating parameters 118 at an operating parameter database 116. The operating parameter database 116 can include one or more computer readable storage media that operate to store digital data. The operating parameter database 116 can be part of the computing device 114 or separate but in data communication with the computing device 114.

FIG. 8 is a schematic block diagram illustrating recommended operating parameters 118. In the example, test run data 111, the operating parameter database 116, and installation specifications 117 are also shown.

Test run data 111 is the data recorded for test runs performed at the transmission line failure testing system 102. A schematic diagram illustrating test runs at the transmission line failure testing system 102 was described in relation to FIG. 5. Data entries for three separate tests are illustrated in FIG. 8. As illustrated in FIG. 8, the test run data 111 for each test can include data related to the advancement device 106 used in the test, the transmission line 110 used in the test, the environmental conditions present during the test, the operating parameters used to advance the transmission line in the test, and the test result. In the example illustrated in FIG. 8, the test run data 111 includes an advancement line identification number for the advancement device 106 used to convey a transmission line for a given test. Similarly, the test run data 111 includes the transmission line identifier of the transmission line 110 conveyed during the test. In other examples, test run data 111 can include any of the advancement device specifications or transmission line specifications for the advancement device 106 and transmission line 110 used in the test. The environmental conditions in the test run data 111 illustrated in FIG. 8 include a temperature, a humidity, and an indication that the test took place in the shade. Finally, the test run data 111 includes test results providing a determination of whether each of the tests passed or failed. As previously discussed, in some embodiments the test run data 111 can include a variety of other information.

Installation specifications 117 are the specifications for a transmission line installation to be performed at the transmission line installation system 120. In the example illustrated in FIG. 8, the installation specifications 117 may include advancement device specifications, transmission line specifications, and environmental conditions. For example, the advancement device specifications can include an advancement device identifier number. Similarly, the transmission line specifications can include a transmission line identifier. In the example illustrated in FIG. 8, the environmental conditions of the installation specifications include a temperature, a humidity, and an indication that the installation is taking place in the shade.

Recommended operating parameters 118 are the parameters to be applied at the advancement device 106 of the transmission line installation system 120. For example, the recommended operating parameters 118 can include a clamp force and a push force, or other operating parameters.

Still in reference to FIG. 8, the test run data 111 can be accessed at the operating parameter database 116 for further processing by the operating parameters provider 112 or other systems to translate the test run data 111 into recommended operating parameters 118. In the example shown in FIG. 8, the test run data 111 can be generated into one or more data entries providing recommended operating parameters based on the test run data 111. Generating recommended operating parameters based on the test run data 111 can include identifying all test runs having selected characteristics, finding the maximum operating parameters resulting in a passing test within the identified test runs, and assigning those maximum operating parameters as recommended operating parameters for the selected characteristics. Selected characteristics can include one or more of: one or more advancement device specifications, one or more transmission line specifications, or one or more environmental conditions. For example, the test run data 111 in FIG. 8 illustrates three tests having the same advancement device ID, transmission line ID, and environmental conditions. In some embodiments, the second test may have included the maximum operating parameters that resulted in a passing test. In some embodiments, these parameters can then be stored as recommended operating parameters 118 at the operating parameter database 116.

In another possible embodiment, the recommended operating parameters can be selected such that there is a margin equal to or greater than a predetermined operating buffer between the recommended operating parameters and a point of failure. The point of failure is the point at which the operating parameters are known to have caused a failure during failure testing. As an example, the operating buffer can be a percentage, such as 3%, 5%, 10%, 15%, and the like. In an example, a calculation is performed that computes the recommended operating parameters to have a margin of at least the operating buffer percentage away from the point of failure determined by the failure testing system. In some embodiments, the maximum operating parameters are first selected as discussed above, and then the maximum operating parameters are evaluated to determine whether there is a sufficient margin between the maximum operating parameters and the failure point. If so, then the maximum operating parameters are selected as the recommended operating parameters. If not, then the recommended operating parameters are selected using the operating buffer calculations.

As further illustrated in FIG. 8, in one embodiment, recommended operating parameters 118 can be stored at the operating parameter database 116 in relation to a set of installation specifications 117. In some embodiments, the recommended operating parameters 118 can be calculated based on the test run data 111. For example, as illustrated in FIG. 8, the recommended operating parameters 118 may be the maximum operating parameters that resulted in a passing test for the advancement device, transmission line, and environmental conditions included in the test run data 111.

In some embodiments, the environmental conditions can include a range of environmental conditions calculated based on the environmental conditions included in the test data 111. For example, a range of environmental conditions can include a temperature range, a humidity range, or a percentage of shade. In other embodiments, rather than calculating and storing recommended operating parameters, the test run data 111 may be used as a searchable library. For example, a user can input installation specifications 117 to the operating parameters provider 112 which can then perform a search of the test run data 111 to identify a passing test for a test using the same or similar advancement device, transmission line, and environmental conditions. For example, if there is more than one passing test corresponding with the provided installation specifications 117, then the operating parameters provider 112 can identify the passing test with the highest operating parameters to determine recommended operating parameters 118. In some embodiments, if there is not an exact match for the installation specifications, the operating parameters provider 112 can calculate recommended operating parameters 118 based on similar test run data. For example, if the exact transmission line specifications are not found in the test run data 111, then test run data for a transmission line with similar characteristics may be utilized. In another example, if the exact environmental conditions are not found in the test run data 111, then test run data with the closest environmental conditions may be utilized and the recommended operating parameters 118 calculated by operating parameters provider 112 may be adjusted according to the difference in the environmental conditions.

FIG. 9 is a flow chart illustrating an example method of determining recommended operating parameters. In this example, the method 204 includes operations 242, 244, and 246.

The operation 242 is performed to receive installation specifications 117 from the transmission line installation system 120 at the operating parameters provider 112.

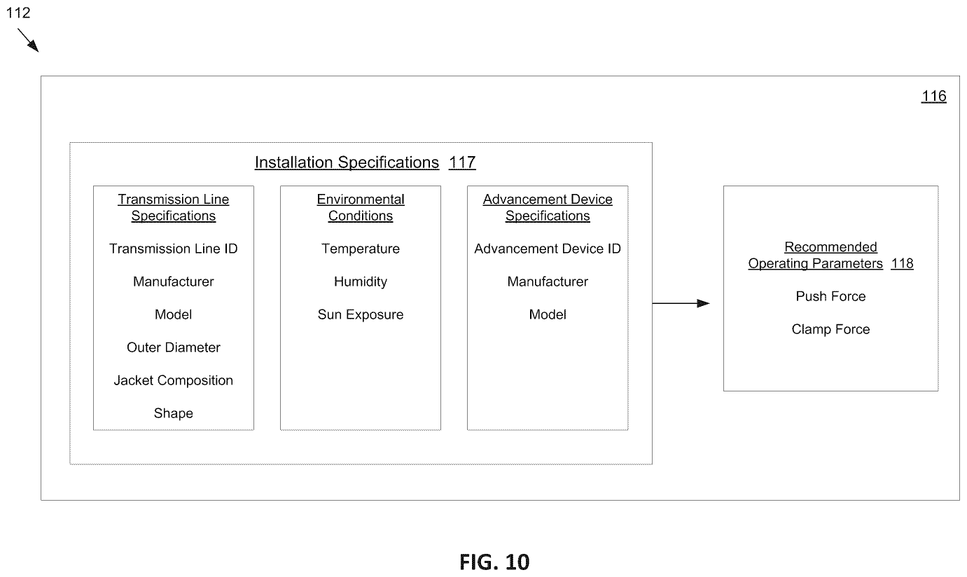

The operation 244 is performed to identify appropriate operating parameters at the operating parameter database 116 in response to the installation specifications 117 received from the transmission line installation system 120. For example, the operating parameters provider 112 can conduct a search of the operating parameter database 116 to identify appropriate operating parameters 118 based on the installation specifications 117 transmitted by the transmission line installation system 120. In some embodiments, the operating parameter database 116 is at the operating parameters provider 112. In other embodiments, the operating parameter database 116 is stored at a secondary storage device remote from the operating parameters provider 112. The operating parameter database 116 can be stored at a computer readable storage media including local storage or cloud-based storage. Additionally, some embodiments include non-transitory media. An example of operation 244 is illustrated and described in more detail herein with reference to FIG. 10.

The operation 246 is performed to provide recommended operating parameters 118 from the operating parameters provider 112 to the transmission line installation system 120. In some embodiments, the operating parameters 118 are sent by the computing device 114 of the operating parameters provider 112 to the transmission line installation system 120.

FIG. 10 is a schematic block diagram illustrating recommended operating parameters 118 generated at the operating parameters provider 112 in response to installation specifications 117 received from the transmission line installation system 120. In the example, the operating parameter database 116 is also shown.

Installation specifications 117 are the specifications for a transmission line installation to be performed at the transmission line installation system 120. In the example illustrated in FIG. 10, the installation specifications 117 include transmission line specifications such as a transmission line identifier, a transmission line manufacturer, a transmission line model, a transmission line outer diameter, a transmission line jacket composition, a transmission line shape, or other transmission line specifications. Other transmission line specifications may also be provided. In some embodiments, the transmission line identifier may not be available so only material composition, dimension, and other visible attributes can be provided. The installation specifications 117 also include environmental conditions such as a temperature, a humidity, a level of sun exposure, or other environmental conditions. In some embodiments, other environmental conditions can also be provided. Installation specifications 117 can also include advancement device specifications such as an advancement device identifier, manufacturer, model name or number, or other specifications of an advancement device. Other advancement device specifications can also be provided.

Recommended operating parameters 118 are the parameters to be applied at the advancement device 106 of the transmission line installation system 120. For example, the recommended operating parameters 118 can include a clamp force and a push force. The recommended operating parameters are calculated in response to the installation specifications. Examples of calculating operating parameters at the operating parameters provider are discussed in relation to FIG. 8.

FIG. 11 is a perspective view illustrating portions of the transmission line installation system 120 shown in FIG. 1. In this example, the transmission line installation system 120 includes a transmission line source 122, a transmission line 124, a line conveying apparatus 104, an advancement device 106, a conduit 107, and a computing device 125.

The transmission line source 122 contains a length of transmission line 124 to be installed. In some embodiments, the transmission line source 122 includes a reel stand, that holds a reel containing a transmission line spooled thereon. The reel stand can include a motorized drive that controls a feed rate at which the transmission line is fed from the transmission line source 122. Some embodiments further include a line counter, that measures the amount of the transmission line and/or the feed rate. Some embodiments include a motorized brake that can be used to slow down or stop the feeding of the transmission line.

In some examples, the transmission line source 122 is stored on a reel. The reel has a body on which the transmission is wound around. In some embodiments the transmission line source 122 and/or the transmission line 124 can include a transmission line identifier thereon. In some embodiments, the transmission line 124 can include specifications such as a manufacturer, a model, an outer diameter, a material composition, or a shape. An example of a material composition can be a jacket composition. In some embodiments the transmission line specifications are associated with the transmission line identifier.

The advancement device 106 is used to convey the transmission line 122 into a conduit 107. In some embodiments, the advancement device 106 can include specifications such as an advancement device identifier.

The conduit 107 receives the transmission line 124 after it is advanced by the advancement device 106. An example of conduit 107 is a duct. The conduit 107 can have a variety of configurations, including different inner and outer diameters, different thicknesses, different surface textures, different surface coatings, and different material compositions.

The computing device 125 is used to send and receive information from and to the operating parameters provider 112. Information sent by the computing device 125 to the operating parameters provider 112 can include installation specifications. For example, the installation specifications can include at least one of: (i) a type of transmission line conveying apparatus 104, (ii) a type of transmission line 124, (iii) a type of conduit 107, (iv) environmental conditions at the transmission line installation system 120, or (v) combinations of (i), (ii), (iii), or (iv). In some embodiments, the computing device 125 can receive recommended operating parameters 118 from the operating parameters provider 112. The recommended operating parameters 118 can then be used to install the transmission line 124.

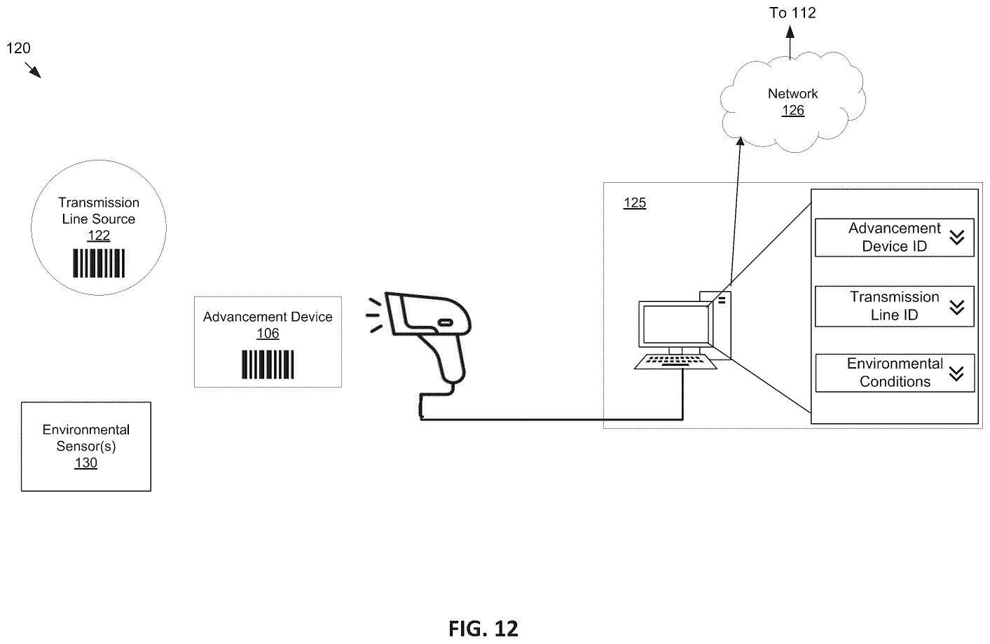

FIG. 12 is a schematic block diagram illustrating installation specifications being transmitted from the transmission line installation system 120 to the operating parameters provider 112. In this example, transmission line source 122, advancement device 106, environmental sensor(s) 130, computing device 125, and network 126 are shown.

As illustrated in FIG. 12, transmission line source 122 can be encoded with machine-readable information such as a barcode, a universal product code (“UPC”), a quick-response (“QR”) code, or radio frequency identification (“RFID”) tag. The computer scannable information can convey transmission line specifications. For example, the computer scannable information can convey a transmission line identifier. In some embodiments, the transmission line 124 can include scannable information.

As illustrated in FIG. 12, advancement device 106 can be encoded with machine-readable information such as a barcode, UPC code, QR code, or RFID tag. The computer scannable information can convey advancement device specifications. For example, the computer scannable information can convey an advancement device identifier.

Environmental sensor(s) 130 are used to identify environmental conditions at the transmission line installation system 120. Environmental sensor(s) can include a temperature sensor, a humidity sensor, a sensor to determine a level of shade or sunshine, A temperature sensor can be a thermometer. A humidity sensor can be a hygrometer. A sensor to determine a level of shade or sunshine can be an ultraviolet (UV) light sensor. In some embodiments, the environmental sensor(s) 130 can be separate from the transmission line installation system 120. In some embodiments, the environmental sensor(s) 130 can receive environmental conditions data from remote sources such as the National Weather Service or other weather forecast providers. In some embodiments, the environmental sensor(s) can be encoded with machine-readable information such as a barcode, UPC code, QR code, or RFID tag.

Computing device 125 can receive installation specifications 117. In some embodiments, the computing device 125 receives manual input from an operator defining the installation specifications 117 of the transmission line installation system 120. In some embodiments, the installation specifications 117 can be automatically populated by receiving input from a scanner device. For example, the scanner device can be a barcode scanner, QR code scanner, or RFID scanner. The scanner device can be used to scan codes at the transmission line source 122, the transmission line 124, the advancement device 106, or the environmental sensor(s) 130. computing device 125 can receive input with a barcode scanner device.

The installation specifications are sent by the computing device 125 to the operating parameters provider 112, which uses the installation specifications to determine appropriate operating parameters 118 for the transmission line installation system 120.

Network 126 is shown for communication between the transmission line installation system 120 and other systems. The network 126 is one or more data communication networks that individually or collectively provide a data communication channel between the transmission line installation system 120 and other systems, such as the operating parameters provider 112.

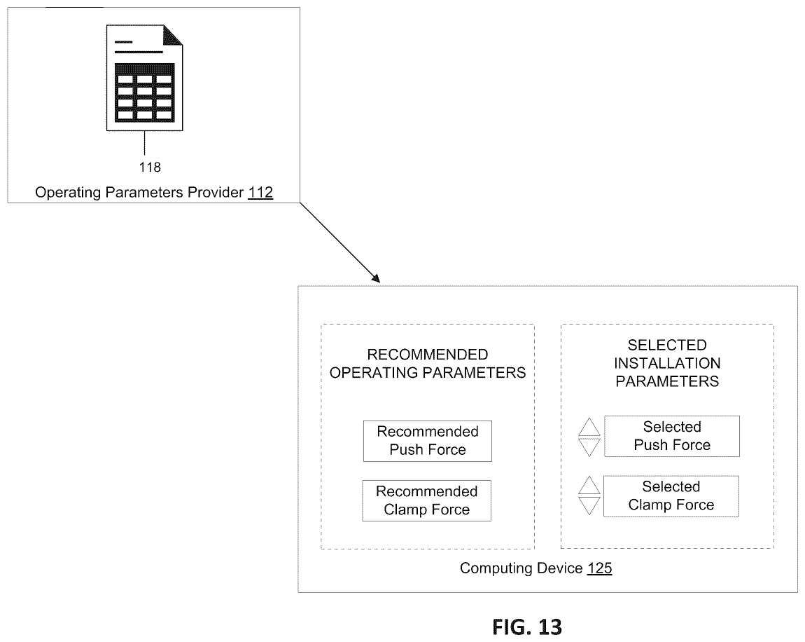

FIG. 13 is a schematic block diagram illustrating recommended operating parameters 118 being received from the operating parameters provider 112 at the computing device 125 of the transmission line installation system 120.

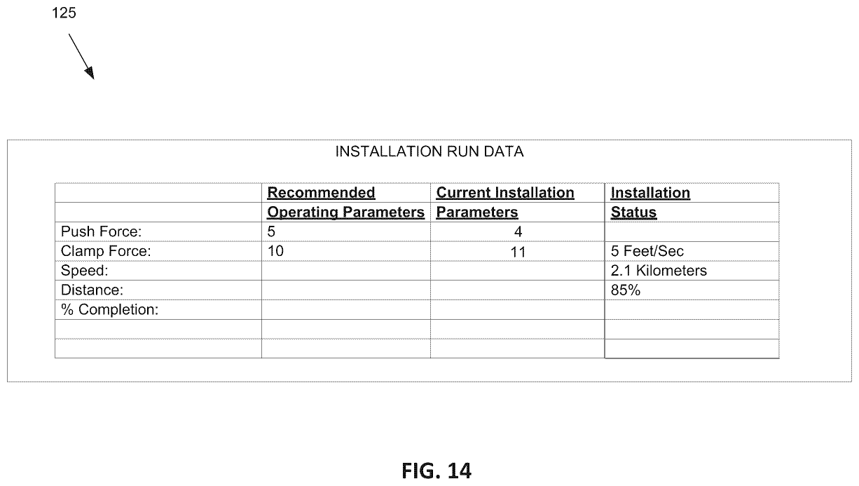

As illustrated in FIG. 13, the computing device 125 can include a user interface. The user interface at the computing device 125 can optionally include a screen displaying the recommended operating parameters 118 received from the operating parameters provider 112. In some embodiments, the transmission line installation system 120 can be automatically configured with the recommended operating parameters. For example, the transmission line installation system 120 may be configured not to exceed the recommended operating parameters. In other embodiments, a user can manually input installation parameters selected by the user. Installation parameters can be different from the recommended operating parameters 118. In some embodiments, the installation parameters can be monitored at the user interface during a transmission line installation. A user interface illustrating a user interface for monitoring installation parameters is depicted in FIG. 14.

FIG. 14 illustrates an example user interface at the computing device 125 for monitoring installation run data during transmission line installation.

As illustrated in FIG. 14, the installation run data shown on the user interface of the computing device 125 can include recommended operating parameters, current installation parameters, and installation status information. For example, installation status information can include an installation speed, the total length of transmission line installed, and a percent completion. The recommended operating parameters, current installation parameters, and installation status information can be shown on the same screen or, in some embodiments, can be accessed in separate screens at the user interface.

Still in reference to FIG. 14, in some embodiments, the user interface can be used to monitor whether the current installation parameters are outside of the recommended operating parameters. In some examples the current installation parameters may be automatically determined by the transmission line installation system or, in other examples, may be manually selected by an operator. The user interface may provide a visual alert to indicate whether the current installation parameters are outside of the recommended operating parameters. For example, if the current installation parameters exceed the recommended installation parameters by a certain percentage, then the computing system 125 may provide an audible alert or a visual alert at the user interface. For example, a visual alert at the user interface may be a first color if the current installation parameters are equal to the recommended operating parameters, a second color if the current installation parameters are within a first range of the recommended operating parameters, and a third color if the current installation parameters are within a second range of the recommended operating parameters.

FIG. 15 is a perspective view of the example line conveying apparatus 104 in FIG. 11. In this example, the line conveying apparatus 104 includes an advancement device 106. The advancement device 106 includes a transmission line receptacle 132, tractor drive 134 including an upper tractor drive 136 and a lower tractor drive 138, a conduit receptacle 140, and a stand 142. Also shown is a computing device 125. The parts are discussed in further detail with reference to FIG. 17.

Still in reference to FIG. 15, the computing device 125 can be incorporated with the line conveying apparatus 104 or the advancement device 106. In some embodiments, the computing device 125 can be separate from the line conveying apparatus 104.

FIG. 16 is a schematic block diagram of the example advancement device 106 of the transmission line conveying apparatus 104 shown in FIG. 11s. In this example, the advancement device 106 includes a frame 156, a transmission line receptacle 132 for receiving a transmission line 124, a transmission line drive assembly 141, a computing device 125, a compressor 158, an air hose 160, an air input port 154, a valve 155, a line blower assembly 138, an air block 152, a conduit receptacle 140, an outlet 162, a conduit 107, and a distal end 127 of the transmission line 124. The transmission line drive assembly 141 includes a tractor drive 134 including the upper tractor drive 136 and the lower tractor drive 138, a pressure source 144, a clamp cylinder 147, an upper drive motor 143, and a lower drive motor 145. Also shown is a transmission line source 122 including a reel stand 146 and a transmission line reel 148.

The advancement device 106 generates force(s) for the installation of the transmission line 124 to be pulled from the transmission line reel 148, or other transmission line source, and inserted into conduit 107. The force(s) may be adjusted based on operating parameter(s) that are selected. The advancement device 106 accepts the transmission line 124 the transmission line receptacle 132, and the transmission line 124 exits the advancement device 106 at the outlet 162.

The force generated by the advancement device 106 can include a pushing force generated by frictional engagement of the transmission line 124 with a transmission line drive assembly 141. The advancement device 106 includes a transmission line drive assembly 141, which frictionally engages the transmission line 124 to provide a pushing force. In some embodiments, the transmission line drive assembly 141 is hydraulically driven by a pressure source 144 linked by hydraulic lines to the transmission line drive assembly 141. Pressure source 144 can be a hydraulic pressure source. In some embodiments, the pressure source 144 can be outside of the transmission line drive assembly 140.

In some embodiments the force can further include a pulling force generated by air pressure. The advancement device 106 preferably also includes the line blower assembly 138, which allows for pressurized air to enter the conduit 107. Line blower assembly 138 is linked to the compressor 158, which generates appropriate air pressure. The air hose 160 and a valve 155 link the compressor 158 with the line blower assembly 138. The valve 155 can be manually or electronically adjustable. An electronically adjustable valve is electronically connected to the local controller, which can adjust the valve between open and closed positions, or to various partially opened positions, to adjust the air flow through the blower and into the conduit 107. Air pressure within the conduit 107 causes the transmission line 124 to move toward the distal end of the conduit 107 where it exits the conduit 107. The pressurized air within the conduit 107 flows along sides of the transmission line 124 which can generate a pulling force at the distal end 127 of the transmission line 124. The flow of air can also generate a pillow of air that helps to space the transmission line 124 from the interior surface of the conduit 107 to reduce frictional contact between the transmission line 124 and the conduit 107. Further if the carrier does not completely seal the duct, the air will flow along the conduit 107 at a faster speed than the transmission line 124. This creates a distributed viscous drag between the air flow and the transmission line 124 that further helps to propel the fiber along the conduit 107 by pulling on the transmission line 124 along the entire length of the transmission line 124. A further advantage of this is that it reduces the required pushing and pulling forces that are localized to the distal and proximal ends of the transmission line, which if too great can result in damage to the transmission line 124.

In some embodiments the advancement device 106 also includes a frame 156, which can be supported by legs, a cart, or other stand for supporting the frame 156 at a convenient level above the ground. As shown in FIG. 16, such supporting structure also includes wheels in some embodiments, for conveniently moving the advancement device 106 between locations. Frame 156 also supports the transmission line drive assembly 141 and the line blower assembly 138. The frame 156 can also support the computing device 125 which monitors and/or controls operation of various of the parts of advancement device 106. In some embodiments, the computing device 125 may be separate from the frame 156. The frame 156 allows for the various assemblies to be conveniently used and transported together as a unit.

The line blower assembly 138 includes the air block 152 which links both the transmission line 124 received from the transmission line drive assembly 141, and the compressor 158 with conduit 107.

In some embodiments the transmission line drive assembly 141 includes the upper and lower tractor drives 136, 138. Preferably, each is driven by a hydraulic, pneumatic, or electric motor, 143, 145. Each tractor drive 136, 138 includes a moveable member. In some embodiments, an endless chain in each tractor drive 136, 138 is driven by the hydraulic motors 143, 145, respectively, to frictionally engage the transmission line 124 and apply the pushing force to the transmission line 124. In the illustrated embodiment, the tractor drives 136, 138 oppose each other and are aligned in the vertical direction. Other moveable drive members besides opposed endless chains are possible including wheels and/or belts.

In some embodiments, a lower drive counter can monitor movement of the lower tractor drive 138, which is indicative of the speed of transmission line drive assembly 141. Such speed monitoring is important for preventing excessive relative speed between the transmission line drive assembly 141 and the transmission line 124 during slippage. The speed is communicated from the lower drive counter to the computing device 125 which receives the speed. The speed may indicate that the operating parameters need to be adjusted. The speed can be communicated from the computing device 125 to other systems, such as the operating parameters provider 112.

In some embodiments the transmission line drive assembly 141 further includes a hold down system, such as a hydraulic clamp cylinder 147, linked to the pressure source 144 by a hydraulic line. The clamp cylinder 147 generates a predetermined clamp force on the transmission line 124 between the upper and lower tractor drives 136, 138. Some slip is acceptable. Too much slip can cause transmission line jacket damage. Too much slip may also limit the usefulness of the advancement device 106 if insignificant push forces are generated. The conduit 107 usually contains some irregularities, joints and bends that can keep transmission line 124 from moving smoothly. Unless an appropriate clamp force is generated (not too much slip), the pushing force may be inadequate to overcome the irregularities, and slip may occur too often, causing unnecessary transmission line jacket damage or insignificant transmission line push force. On the other hand, a clamp force which is too high risks crush damage to the transmission line 124, and inadequate slippage, such that damage will be more likely to occur as the transmission line drive assembly 141 continues to move the transmission line 124 when transmission line 124 is being slowed or stopped within the conduit 107. When slip does occur under high clamp force loads, transmission line jacket damage may result. By providing for a predetermined clamp force with the advancement device 106, predetermined slip levels can be monitored. This results in an appropriate level of slip, to not cause too many shutdowns of the advancement device 106 when transmission line damage is not significantly at risk, but excessive slip is noted, and can be used to shut off the advancement device 106 to prevent damage. If excessive slip is noticed, then the operating parameters 118 can be adjusted.

In some embodiments the computing device 125 of the advancement device 106 includes control subsystems for monitoring and controlling operating parameters including: the speed of the upper and lower tractor drives 136, 138; the speed of the transmission line 124; system air pressure; and the clamp force applied by the clamp cylinder 147. In some embodiments, the computing device 125 can communicate installation run data such as installation condition data and successful operating parameters to the operating parameters provider 112. This installation run data can be stored at the operating parameters provider 112 and can be used in generating future recommended operating parameters.

FIG. 17 is a flow chart illustrating an example method of transmission line installation. In this example, the method 206 includes operations 236, 238, 240, 242, 244, and 246.

The operation 236 is performed to determine transmission line installation specifications 117. The transmission line installation specifications 117 can include transmission line specifications, environmental conditions, and advancement device specifications. Transmission line installation specifications 117 are further described in reference to FIG. 10.

The operation 238 is performed to send installation specifications 117 from the d line installation system 120 to the operating parameters provider 112. The installation specifications 117 can be sent by the computing device 125 at the transmission line installation system 120 and received by the computing device 114 of the operating parameters provider 112.

The operation 240 is performed to receive recommended operating parameters 118 at the transmission line installation system 120 from the operating parameters provider 112. The recommended operating parameters can be sent by the computing device 112 of the operating parameters provider 112 and received by the computing device 125 at the transmission line installation system 120.

The operation 242 is performed to configure the transmission line installation system 120 according to the recommended operating parameters 118. The operation 242 can include configuring the operating parameters of the advancement device 106 based on the recommended operating parameters. In some embodiments, the recommended operating parameters can be used. In other embodiments, operating parameters that are outside of the recommended operating parameters can be used. Operating parameters can include a push force and a clamp force.

The operation 244 is performed to perform transmission line installation. An example method of transmission line installation is further described with relation to FIG. 19.

FIG. 18 is a flow chart illustrating an example method of transmission line installation. In this example, the method 208 includes operations 248, 250, 252, 254, and 256.

The operation 246 is performed to begin transmission line installation. Transmission line installation can begin by selecting operating parameters and conveying the transmission line 110 with the conveying apparatus 104. The selected operating parameters can include the recommended operating parameters 118, operating parameters other than the recommended operating parameters 118, or a combination of recommended operating parameters 118 and other operating parameters. The selected operating parameters can include a variation of the recommended operating parameters. A variation of the recommended operating parameters may be selected based on an operator's observations of the transmission line installation system 120 or other conditions. For example, the operator may select a variation of the recommended operating parameters based on changing environmental circumstances, the speed needed to complete the installation, or a risk tolerance level.

The operation 248 is performed to monitor installation specifications 117. The installation specifications 117 can include transmission line specifications, advancement device specifications, or environmental conditions. In some embodiments, the installation specifications 117 can be monitored by an operator of the transmission line installation system 120. In other embodiments, the installation specifications 117 can be monitored by one or more computing systems. For example, the installation specifications 117 can be monitored by the computing system 125.

The operation 250 is performed to determine whether there has been a change in installation specifications 117. A change in installation specifications 117 can be determined by an operator of the transmission line installation system 120. For example, an operator of the transmission line installation system 120 may identify a change in environmental conditions, specifications of conduit 107, a change in transmission line specifications, or a change in the advancement device specifications. A change in the specifications of conduit 107 could include an obstruction, a change in material, a change in size, a change in direction, or other changes. In some embodiments, a change in installation specifications 117 can be determined automatically by one or more computing systems. For example, a change in installation specifications 117 can be determined by the computing system 125. In some embodiments, a weather database may be accessed by the computing system 125 to monitor changes in environmental conditions. In some embodiments, the computing system 125 may be in communication with the conveying apparatus 104 to determine a change in the advancement device specifications.

The operation 252 is performed to adjust installation parameters if there has been a change in installation specifications 117. For example, if the environmental conditions change it can be necessary to adjust installation parameters. The installation parameters may be adjusted by an operator of the transmission line installation system 120 or by one or more computing devices. Adjusting the installation parameters can include sending a new request to the operating parameters provider 112 with the updated installation specifications and receiving updated recommended operating parameters 118 from the operating parameters provider 112. In some examples, an operator may decide not to adjust installation parameters based on a change in installation specifications 117.

The operation 254 is performed to continue transmission line installation. If there is no change in installation specifications 117, the transmission line installation can be continued. Alternatively, if there is a change in installation specifications 117, once the installation parameters have been adjusted, the transmission line installation can be continued. In some examples, an operator can continue the transmission line installation without adjusting the installation parameters based on a change in installation specifications 117. In some embodiments, the transmission line installation can be continued until the transmission line installation process has been completed.

The present disclosure and claims sometimes utilize the words “first,” “second,” “third,” etc. as labels to particularly identify particular objects. Unless required by the context, such terms are used only as labels and do not require any particular order or arrangement with respect to each other or with respect to other objects.

The various embodiments described above are provided by way of illustration only and should not be construed to limit the claims attached hereto. Those skilled in the art will readily recognize various modifications and changes that may be made without following the example embodiments and applications illustrated and described herein, and without departing from the true spirit and scope of the following claims.

What is claimed is:

1. A method for mitigating damage to a transmission line during installation, the method comprising:
conducting failure testing to determine a failure condition of a transmission line;
determining recommended operating parameters for installation of the transmission line using a transmission line installation system based at least in part on the failure testing;
storing the recommended operating parameters in a data store;
retrieving the recommended operating parameters from the data store;
setting up the transmission line installation system based at least in part on the recommended operating parameters; and
installing a transmission line using the transmission line installation system.

2. The method of claim 1, further comprising monitoring installation progress and controlling the transmission line installation system to prevent the transmission line installation system from reaching the failure condition of the transmission line.

3. The method of claim 1, wherein the recommended operating parameters are associated with the transmission line and the transmission line installation system in the data store.

4. The method of claim 1, wherein conducting failure testing to determine failure conditions of one or more transmission lines further comprises:
providing a first transmission line;
providing a conduit;
providing an obstruction to the conduit;
applying one or more operating parameters at a transmission line conveying apparatus;
conveying the transmission line through the transmission line conveying apparatus and into the obstruction; and
inspecting the transmission line for damage.

5. The method of claim 4, wherein conducting failure testing to determine a failure condition further comprises:
lowering at least one of the one or more operating parameters if the transmission line is damaged.

6. The method of claim 4, wherein conducting failure testing to determine a failure condition further comprises:
raising at least one of the one or more operating parameters if the transmission line is not damaged.

7. The method of claim 1, wherein the data store is an operating parameter database, and wherein determining recommended operating parameters further comprises:
receiving installation specifications from the transmission line installation system;
identifying appropriate operating parameters at the operating parameter database; and
providing recommended operating parameters from the operating parameters
database to the transmission line installation system.

8. The method of claim 1, wherein setting up a transmission line installation system further comprises:
determining transmission line installation specifications;
sending the transmission line installation specifications to an operating parameters provider;
receiving recommended operating parameters at the transmission line installation system from the operating parameters provider; and
configuring the transmission line installation system according to the recommended operating parameters.

9. The method of claim 1, wherein installing a transmission line further comprises:
selecting one or more operating parameters;
conveying the transmission line with a conveying apparatus using the one or more operating parameters;
monitoring one or more installation specifications;
determining whether there has been a change in the one or more installation specifications; and
adjusting the installation parameters when determined that there has been the change in the one or more installation specifications.

10. A method for generating recommended installation parameters associated with a transmission line, the method comprising:
testing the transmission line at a transmission line testing system to generate test run data;
accessing the test run data at an operating parameters provider;
identifying test runs having selected characteristics;
identifying maximum operating parameters resulting in a passing test within the test runs having selected characteristics; and
assigning recommended operating parameters based at least in part on the maximum operating parameters.

11. The method of claim 10, wherein the selected characteristics includes one or more of:
one or more advancement device specifications;
one or more transmission line specifications; and
one or more environmental conditions.

12. The method of claim 11, wherein the one or more environmental conditions include at least one of: temperature, humidity, sunlight, shade, or precipitation.

13. The method of claim 10, wherein the recommended operating parameters are selected as the maximum operating parameters.

14. The method of claim 10, wherein assigning the recommended operating parameters further comprises:
determining whether a margin between the maximum operating parameters and a point of failure is equal to or greater than an operating buffer;
when the margin is equal to or greater than the operating buffer, selecting the maximum operating parameters as the recommended operating parameters; and
when the margin is not equal to or greater than the operating buffer, computing the recommended operating parameters to maintain the margin between the recommended operating parameters and the point of failure.

15. A system for determining recommended operating parameters for a transmission line installation system, the system comprising;
a transmission line failure testing system configured to perform tests on one or more transmission lines to generate test run data;
an operating parameters provider configured to receive the test run data from the transmission line failure testing system, generate recommended operating parameters from the test run data, and store the recommended operating parameters at an operating parameters database; and
a transmission line installation system configured to receive the recommended operating parameters from the operating parameters provider, and install a transmission line according to the recommended operating parameters.

16. The system of claim 15, wherein the transmission line failure testing system further comprises:
a transmission line conveying apparatus;
an obstructed conduit; and
a computing device for storing test run data.

17. The system of claim 15, wherein the operating parameters provider further comprises a network-connected computing device configured to receive a request for the recommended operating parameters from the transmission line installation system, and to supply the recommended operating parameters to the transmission line installation system responsive to the request.

18. The system of claim 15, wherein the transmission line failure testing system replicates environmental factors that can affect the properties of a transmission line or conduit.

19. The system of claim 15, wherein the transmission line installation system further comprises:
a computing device to record test data; and
a network for communication between the transmission line failure testing system and the operating parameters provider.

20. The system of claim 15, wherein the test run data includes:
characteristics of the one or more transmission lines;
characteristics of one or more advancement devices;
environmental factors; and
operating parameters that were used for the tests.

21. The system of claim 15, wherein the transmission line failure testing system is in communication with the operating parameters provider.

22. The system of claim 15, wherein the transmission line installation system further comprises:
one or more environmental sensor to identify environmental conditions at the transmission line installation system.

23. The system of claim 22, wherein the one or more environmental sensors include a temperature sensor, a humidity sensor, or an ultraviolet light sensor.

24. The system of claim 15, wherein the transmission line installation system further comprises:
a computing device configured to receive installation specifications.

25. The system of claim 24, wherein the computing device is further configured to transmit installation specifications to the operating parameters provider.

26. The system of claim 24, wherein the computing device is further configured to receive recommended operating parameters from the operating parameters provider.
